(19) United States
(12) Patent Application Publication
(10) Pub. No.: US 2013/0321902 A1
(43) Pub. Date: Dec. 5, 2013

(54) LOW-LOSS FLEXIBLE META-MATERIAL AND METHOD OF FABRICATING THE SAME

(71) Applicant: ELECTRONICS AND TELECOMMUNICATIONS RESEARCH INSTITUTE, (US)

(72) Inventor: Choon Gi CHOI, Daejeon (KR)

(73) Assignee: ELECTRONICS AND TELECOMMUNICATIONS RESEARCH INSTITUTE, Daejeon (KR)

(21) Appl. No.: 13/830,695

(22) Filed: Mar. 14, 2013

(30) Foreign Application Priority Data
Jun. 5, 2012 (KR) 10-2012-0060350
Nov. 13, 2012 (KR) 10-2012-0128335

(51) Int. Cl. H01S 5/34; G02B 1/00

(52) U.S. Cl. CPC H01S 5/34; G02B 1/007; Y10S 977/755; Y10S 977/774; B82Y 20/00
USPC 359/344; 216/24; 359/333; 977/755; 977/774

(57) ABSTRACT

Provided are a meta-material and a method of fabricating the same. the metal-material may include a substrate, a metal layer on the substrate, and an active gain medium layer on the metal layer. The active gain medium layer and the metal layer may be configured to define hole patterns that may be periodically arranged to have a space smaller than a wavelength of an ultraviolet light, such that the active gain medium layer and the metal layer exhibit a negative refractive index in a wavelength region of the ultraviolet light.

### CROSS-REFERENCE TO RELATED APPLICATIONS

This U.S. non-provisional patent application claims priority under 35 U.S.C. §119 to Korean Patent Application Nos. 10-2012-00060350 and 10-2012-00128335, filed on Jun. 05, 2012, and filed on Nov. 13, 2012, respectively, in the Korean Intellectual Property Office, the entire contents of which are hereby incorporated by reference.

### BACKGROUND OF THE INVENTION

Example embodiments of the inventive concept relate to a low-loss flexible meta-material and a method of fabricating the same.

Meta-materials are artificial materials engineered to include periodically-arranged artificial elements. The meta-material may include inner structures having a size much larger than molecules. Accordingly, a propagation path of an electromagnetic wave incident to the meta-material can be described by solving macroscopic Maxwell equations. By contrast, an inner structure of the meta-material may have a size much smaller than a wavelength of the electromagnetic wave. Accordingly, the meta-material may include structures, whose shape and size are configured in such a way that macroscopic material response properties are determined by a spectrum component of a near field region thereof

The meta-materials are formed of conventional materials (such as metals or semiconductor) but include small and repeatedly-arranged patterns, thereby exhibiting a collective property changed from that of the conventional material. For example, the meta-material structure may exhibit a negative refractive index, unlike a positive refractive index of the conventional material. Due to the negative refractive index, electromagnetic wave may be reflected from the meta-material along a direction opposite to a direction that is expected by Snell's law. This property may be used to overcome a diffraction limitation of conventional optical lens or to realize a super lens with super-resolution of less than one-seventh of a wavelength of an incident light. Further, due to the diffraction limitation, a resolution of an atomic force microscope or a scanning electron microscope is limited to a range of greater than half of a wavelength in conventional ways, but the use of the meta-material may be used to overcome this limitation. In addition, the meta-material may be widely used in various technologies (e.g., biological and micro-electronic technologies) and be expected to be able contribute to the advancement in a novel imaging technology and an ultra-microscopic process.

Conventionally, split ring resonator (SRR), double SRR, and cut-wire pair structures have been suggested to realize the meta-materials. However, the conventional meta-materials suffer from a loss of electric field caused by a metal layer. There has been a research for realizing a low-loss negative refractive meta-material in a visible wavelength region, and the research shows that a figure of merit, which may be defined by a ratio of the real part to the imaginary part of the refractive index, can be increased. However, there is no report of an experimental realization of a low-loss meta-material in an ultraviolet wavelength region.

### SUMMARY

Example embodiments of the inventive concept provide a low-loss flexible meta-material, which can be operated in an ultraviolet wavelength region, and a method of fabricating the same.

Other example embodiments of the inventive concept provide a low-loss flexible meta-material capable of overcoming the diffraction limitation of optical lens and realizing a super lens, and a method of fabricating the same.

Still other example embodiments of the inventive concept provide a low-loss flexible meta-material, which can be fabricated with increased productivity and production yield, and a method of fabricating the same.

According to example embodiments of the inventive concepts, a meta-material provided with a hole pattern may include a substrate, a metal layer on the substrate, and an active gain medium layer on the metal layer. The active gain medium layer and the metal layer may be configured to define hole patterns that may be periodically arranged to have a space smaller than a wavelength of an ultraviolet light, such that the active gain medium layer and the metal layer exhibit a negative refractive index in a wavelength region of the ultraviolet light.

In example embodiments, the active gain medium layer may include a dye layer, a quantum well layer or a quantum dot.

In example embodiments, the quantum dot and the quantum well layer may include a semiconductor layer.

In example embodiments, the semiconductor layer may include gallium nitride or silicon carbide.

In example embodiments, the quantum dot and the quantum well layer may include a metal semiconductor layer.

In example embodiments, the metal semiconductor layer may include aluminum gallium nitride or indium gallium nitride.

In example embodiments, the dye layer may include coumarin, fluorescein, rhodamine, mbelliferone, PMMA, ORMOSILs, or metal oxide including ZnO.

In example embodiments, the metal oxide may include zinc oxide.

In example embodiments, the substrate may include a flexible substrate.

In example embodiments, the flexible substrate may include polyimide, fused silica, or PDMS.

According to example embodiments of the inventive concepts, a method of fabricating a meta-material may include forming a sacrificial layer on a substrate, forming a flexible substrate on the sacrificial layer, alternatingly forming at least one metal layer and at least one active gain medium layer on the flexible substrate, separating the flexible substrate from the sacrificial layer, and forming hole patterns in the metal layer and the active gain medium layer.

In example embodiments, the forming of the hole patterns may include a patterning process, in which a focused ion beam may be used.

In example embodiments, the separating of the flexible substrate from the sacrificial layer may include exfoliating the flexible substrate from the sacrificial layer using a chemical or physical exfoliation technique.

In example embodiments, the chemical exfoliation technique may include selectively etching the sacrificial layer

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a perspective view of a low-loss flexible meta-material according to example embodiments of the inventive concept.

FIGS. 2 through 6 are perspective views illustrating a process of fabricating the low-loss flexible meta-material of FIG. 1.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof

Example embodiments of the inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments of the inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

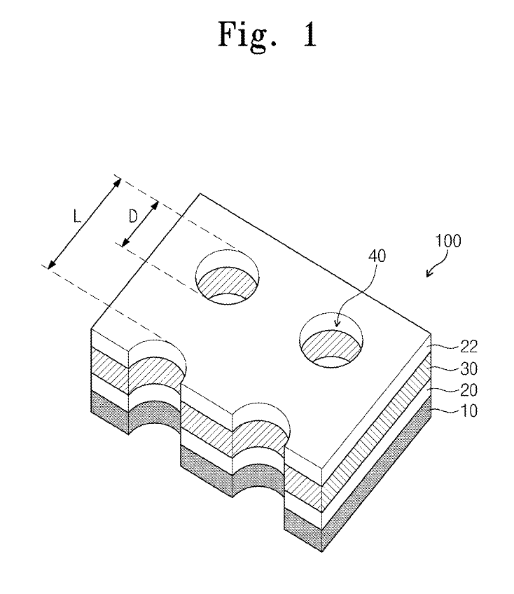

FIG. 1 is a perspective view of a low-loss flexible meta-material according to example embodiments of the inventive concept.

Referring to FIG. 1, a low-loss flexible meta-material 100 may include a flexible substrate 10, a first metal layer 20, an active gain medium layer 30, and a second metal layer 22.

The flexible substrate 10 may be configured to have high transmittance, good flexibility, and good stretch, when an ultraviolet light is incident thereto. For example, the flexible substrate 10 may include a polymeric material, such as polyimide, fused silica or

PDMS.

The first metal layer 20 and the second metal layer 22 may include at least one of metals (e.g., gold (Au), silver (Ag), or aluminum (Al)). In addition, the first metal layer 20 and the second metal layer 22 may include a graphene layer. Each of the first metal layer 20 and the second metal layer 22 may have a thickness of from about 1 nm to about 200 nm.

The first metal layer 20 and the second metal layer 22 may have a thickness adjusted depending on resonance condition given by a wavelength of a beam incident thereto.

The active gain medium layer 30 may be provided between the first metal layer 20 and the second metal layer 22. The active gain medium layer 30 may include at least one of a dye layer, a quantum dot layer, or a quantum well layer. The dye layer may include coumarin, fluorescein, rhodamine, mbelliferone, PMMA, ORMOSILs, or metal oxide (e.g., ZnO).

In example embodiments, the quantum dot and the quantum well layer may include a semiconductor layer (e.g., gallium nitride (GaN) or silicon carbide (SiC)). In other embodiments, the quantum dot and quantum well layer may include a metal semiconductor layer (e.g., aluminum gallium nitride (AlGaN) or indium gallium nitride (InGaN)). The active gain medium layer 30 may have a thickness ranging from about 10 nm to about 500 nm. In example embodiments, the thickness of the active gain medium layer 30 may be determined depending on an energy bandgap of a material constituting the active gain medium layer 30. The active gain medium layer 30 may be configured to compensate a loss of electromagnetic wave, which may be caused by the metal layer. The active gain medium layer 30 may be configured to increase a gain value, when an ultraviolet light is incident thereto. A pump beam may be incident to the active gain medium layer 30. The pump beam may induce photoluminescence of the active gain medium layer 30. The photoluminescence may be configured to compensate a loss of electromagnetic wave, which may be caused by surface plasmon effects of the first metal layer 20 and the second metal layer 22.

According to example embodiments of the inventive concept, the low-loss flexible metal-material 100 may realize a super lens capable of overcoming a diffraction limitation in an optical lens. In addition, the metal-material 100 may be applied to realize a high-resolution bio imaging technology, an ultrasonic imaging technology, a lithography technology for downsizing optoelectronic circuits, a pick-up technology for a next generation storage, an antireflective material, a technology for downsizing antenna/waveguide, an imaging improvement of magnetic resonance imaging (MRI) device, or an artificial structure such as counter-terrorism sensors.

Although not shown, an additional active gain medium layer may be provided on the second metal layer 22. In example embodiments, a plurality of metal layers and a plurality of active gain medium layers may be alternatingly stacked to form a multi-layered structure.

The flexible substrate 10, the first metal layer 20, the active gain medium layer 30, and the second metal layer 22 may be formed to define hole patterns 40 arranged to have a predetermined space. The hole patterns 40 may be configured to improve a negative refractive index property and a figure of merit (−nᵣ/nⱼ), when an ultraviolet light is incident thereto. The hole patterns 40 may be nano-sized patterns configured to have a negative refractive index for a wavelength region of a given electromagnetic wave, and a size, a thickness, and the number thereof may be adjusted. For example, the hole patterns 40 may be formed to have a size and/or a space that are much smaller than a wavelength of an ultraviolet light, and in this case, the low-loss metal-material 100 may exhibit suppressed diffraction and scattering characteristics and a uniform refractive index. In addition, a shape, a size and the number of the hole patterns 40 may be adjusted in such a way that the low-loss metal-material 100 can exhibit a negative refractive index in an ultraviolet wavelength range.

Each of the hole patterns 40 may be formed to have a circular or rectangular shape. In the case where the hole patterns 40 are shaped like a circle, a diameter D and a pitch L thereof may range from about 20 nm to about 1000 nm. This configuration enables to operate properly the low-loss metal-material 100 in an ultraviolet wavelength range.

A method of fabricating the low-loss metal-material 100 according to example embodiments of the inventive concept will be described below.

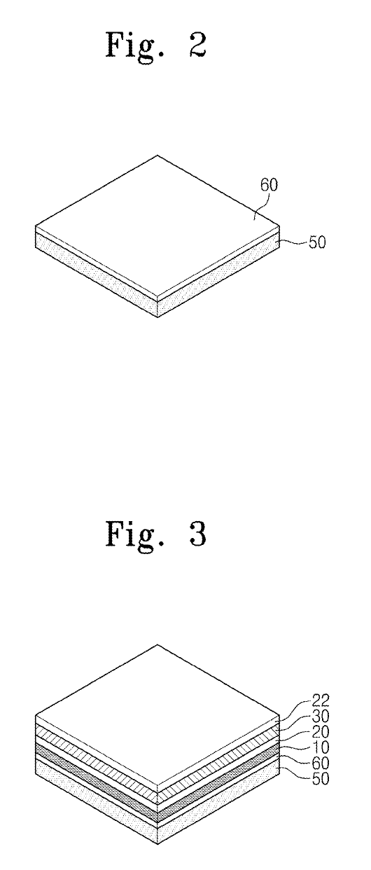

FIGS. 2 through 6 are perspective views illustrating a process of fabricating the low-loss flexible meta-material of FIG. 1.

Referring to FIG. 2, a sacrificial layer 60 may be formed on a flat panel substrate 50. The flat panel substrate 50 may include glass, silicon, or quartz and the sacrificial layer 60 may include nickel. But example embodiments of the inventive concepts may not be limited thereto.

Referring to FIGS. 1 and 3, a flexible substrate 10, a first metal layer 20, an active gain medium layer 30, and a second metal layer 20 may be formed on the sacrificial layer 60. The flexible substrate 10 may include at least one of polymeric materials (e.g., polyimide, fused silica, or PDMS), which may be formed using a spin-coating or printing process. In addition, the polymeric materials may be formed using a chemical vapor deposition process, an E-beam evaporation process, or a thermal evaporation process. The first metal layer 20, the active gain medium layer 30, and a second metal layer 22 may be formed using a chemical vapor deposition process, an atomic layer deposition process, an E-beam evaporation process, or a thermal evaporation process. The flat panel substrate 50 may be configured to perform stably the processes for depositing the first metal layer 20, the active gain medium layer 30 and the second metal layer 22. For example, the flexible substrate 10 may be protected against a high temperature deposition process, due to the flat panel substrate 50.

Accordingly, a low-loss flexible metal-material 100 according to example embodiments of the inventive concept may have an improved productivity and an increased production yield.

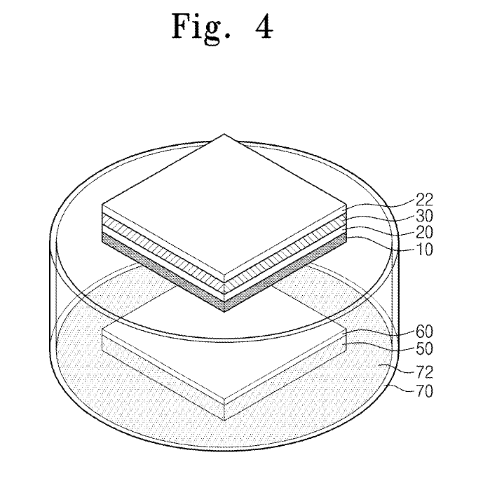

Referring to FIG. 4, the flexible substrate 10 may be exfoliated from the sacrificial layer 60. For example, the sacrificial layer 60 may be removed using an etching solution 72, which may be stored in a chemical bath 70. The removal of the sacrificial layer 60 may include dipping a structure provided with the sacrificial layer 60 into the chemical bath 70 with the etching solution 72. Accordingly, the sacrificial layer 60 may be removed selectively.

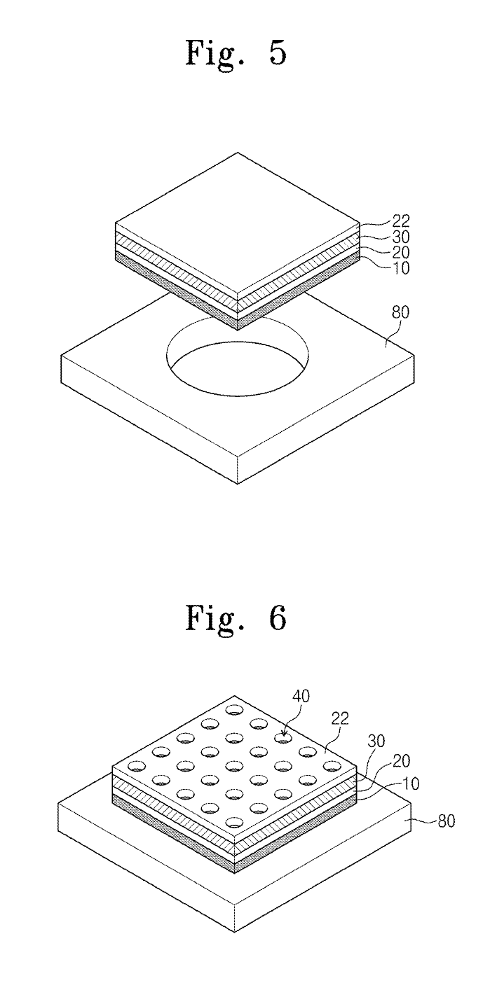

Referring to FIG. 5, the flexible substrate 10 may be provided over a stage 80. The stage 80 may be used to fix the flexible substrate 10.

Referring to FIG. 6, hole patterns 40 may be formed in the second metal layer 22, the active gain medium layer 30, the first metal layer 20 and the flexible substrate 10. The formation of the hole patterns 40 may include patterning the second metal layer 22, the active gain medium layer 30, the first metal layer 20 and the flexible substrate 10 using a focused ion beam.

According to example embodiments of the inventive concept, a meta-material may include a flexible substrate, a metal layer, and an active gain medium layer. The metal layer and the active gain medium layer may be formed to define hole patterns. In addition, the metal layer and the active gain medium layer may be alternatingly and repeatedly stacked on the flexible substrate. The active gain medium layer may include a dye layer with quantum dots or a quantum well layer. The active gain medium layer may be configured to compensate an electromagnetic wave loss, which may be caused by surface plasmon effects of the metal layer. A pump beam may be used to increase a gain value, when an ultraviolet light beam is incident to the active gain medium layer. Accordingly, the meta-material can realize a super lens capable of overcoming a diffraction limitation in an optical lens.

According to other example embodiments of the inventive concept, a flexible substrate may be formed on a flat panel substrate and a sacrificial layer. A metal layer and an active gain medium layer may be formed on the flexible substrate using a high temperature deposition process. The flexible substrate can be protected against thermal damage, which may be caused by the high temperature deposition process. Thereafter, the sacrificial layer may be removed. Accordingly, a low-loss flexible metal-material according to example embodiments of the inventive concept can be fabricated with an improved productivity and an increased production yield.

While example embodiments of the inventive concepts have been particularly shown and described, it will be understood by one of ordinary skill in the art that variations in form and detail may be made therein without departing from the spirit and scope of the attached claims.

What is claimed is:

1. A meta-material provided with a hole pattern, comprising:
a substrate;
a metal layer on the substrate; and
an active gain medium layer on the metal layer,
wherein the active gain medium layer and the metal layer are configured to define hole patterns that are periodically arranged to have a space smaller than a wavelength of an ultraviolet light, such that the active gain medium layer and the metal layer exhibit a negative refractive index in a wavelength region of the ultraviolet light.

2. The meta-material of claim 1, wherein the active gain medium layer comprises a dye layer, a quantum well layer or a quantum dot.

3. The meta-material of claim 2, wherein the quantum dot and the quantum well layer comprises a semiconductor layer.

4. The meta-material of claim 3, wherein the semiconductor layer comprises gallium nitride or silicon carbide.

5. The meta-material of claim 2, wherein the quantum dot and the quantum well layer comprises a metal semiconductor layer.

6. The meta-material of claim 5, wherein the metal semiconductor layer comprises aluminum gallium nitride or indium gallium nitride.

7. The meta-material of claim 2, wherein the dye layer comprises coumarin, fluorescein, rhodamine, mbelliferone, PMMA, ORMOSILs, or metal oxide including ZnO.

8. The meta-material of claim 7, wherein the metal oxide comprises zinc oxide.

9. The meta-material of claim 1, wherein the substrate comprises a flexible substrate.

10. The meta-material of claim 8, wherein the flexible substrate comprises polyimide, fused silica, or PDMS.

11. A method of fabricating a meta-material, comprising:
forming a sacrificial layer on a substrate;
forming a flexible substrate on the sacrificial layer;
alternatingly forming at least one metal layer and at least one active gain medium layer on the flexible substrate;
separating the flexible substrate from the sacrificial layer; and
forming hole patterns in the metal layer and the active gain medium layer.

12. The method of claim 11, wherein the forming of the hole patterns comprises a patterning process, in which a focused ion beam is used.

13. The method of claim 11, wherein the separating of the flexible substrate from the sacrificial layer comprises exfoliating the flexible substrate from the sacrificial layer using a chemical or physical exfoliation technique.

14. The method of claim 13, wherein the chemical exfoliation technique comprises selectively etching the sacrificial layer
